(19) United States
(12) Patent Application Publication
(10) Pub. No.: US 2021/0408988 A1
(43) Pub. Date: Dec. 30, 2021

(54) A SECOND GENERATION CURRENT CONVEYOR (CCII) HAVING A TUNABLE FEEDBACK NETWORK

(71) Applicant: University of Pretoria, Pretoria (ZA)

(72) Inventors: Piotr Jan Osuch, Pretoria (ZA); Tinus Stander, Pretoria (ZA)

(21) Appl. No.: 17/292,208

(22) PCT Filed: Nov. 9, 2018
(86) PCT No.: PCT/IB2018/058805

§ 371 Date: May 7, 2021

(51) Int. Cl. H03F 3/45; H03F 1/34

(52) U.S. Cl. CPC H03F 3/45179; H03F 1/342

(57) ABSTRACT

A Second-Generation Current Conveyor (CCII) has a three-port network with ports designated as X, Y, and Z, wherein the CCII includes a tunable feedback network. The tunable feedback network may be provided between at least two of the ports, e.g., ports Z and Y. The tunable feedback network may comprise a tunable RC (Resister-Capacitor) network which may be provided by solid-state components such as a MOS (Metal-Oxide Semiconductor) device or a MOS resistor (for the resistive element) and a varactor (for the capacitive element).

### FIELD OF INVENTION

This invention relates broadly to Current Conveyors (CCs) and more specifically to Second Generation Current Conveyors (CCIIs) including feedback networks.

### BACKGROUND OF INVENTION

In broad terms, Current Conveyors (CCs) and Second Generation Current Conveyors (CCIIs) are known in the electronic arts (https://en.wikipedia.org/wiki/Current_conveyor, accessed 5 Jun. 2017). Since the introduction of the CCII in the 1970s [1], it has proven to be a versatile building block in analogue electronic design. Systems employing the CCII include active filters [2], impedance converters such as negative impedance converters (NICs), active inductance circuits [1], operational amplifiers, gyrators, mode converters, oscillators [1], [3], controlled voltage and current sources [1], analogue computation elements such as integrators and differentiators [4], current-mode digital-to-analogue (DAC) converters and variable-state filters [5].

A CCII is a three-port network defined by the hybrid matrix:

$$[ \begin{matrix}{I}_{Y} \\ {V}_{X} \\ {I}_{Z}\end{matrix} ] = [ \begin{matrix}{Y}_{Y} & 0 & 0 \\ β & {Z}_{X} & 0 \\ 0 & α & {Y}_{Z}\end{matrix} ] [ \begin{matrix}{V}_{Y} \\ {I}_{X} \\ {V}_{Z}\end{matrix} ] , \qquad ( 1 )$$

where β and α represent the voltage and current transfer ratios respectively, Y_{Y} the admittance at port Y, Z_{X} the impedance at port X and Y_{Z} the admittance at port Z [3]. It is desirable in many applications to minimise the deviation of β and α from unity (here referred to as the transfer error), minimise R_{X} and maximise R_{Z} and R_{Y} (the resistive components of Z_{X}, Y_{Z} and Y_{Y} respectively) for some desired bandwidth.

The first implementations of CCIIs used operational amplifiers as functional blocks due to a lack of high-quality pnp devices in bipolar technology nodes at the time [4]. Research efforts were subsequently focused at finding equivalent CMOS realisations [5], [9], [10]. An example CCII [5] has formed the baseline of many subsequent designs, presenting an R_{X} of less than 50Ω and a transfer error of below 1%. Another example CCII [10] proposed improves on this transfer precision by employing a double feedback mechanism as well as a high-swing cascode current mirror. The added complexity, however, reduces the achievable bandwidth to ˜1 MHz in 0.6 μm CMOS. Furthermore, the efficacy of this approach is only demonstrated in simulation, and not in measurement. On the other hand [9], the CCII from can be simplified by incorporating the common drain feedback amplifier into the differential voltage follower stage. This has the effect of improving the bandwidth (20 MHz in 1.2 μm CMOS) and reducing R_{X} to 0.3Ω. An RC compensation network is also used, for the first time, to reduce peaking.

In an effort to improve bandwidth, an implementation based on a source follower and cascode current mirror stage [11] achieves a bandwidth of 700 MHz in a 1.2 μm CMOS node (for suitable load terminations). However, the resulting R_{X} is large (˜50Ω), illustrating the trade-off between bandwidth and R_{X}. A new high-precision (β and α transfer errors of 30×10-6 and 10-6 respectively) and ultra-low R_{X} (less than 0.1Ω) CCII has been proposed [12]. The design, however, only achieves a bandwidth of 15 MHz in 0.5 um CMOS, demonstrating the trade-off that also exists between bandwidth and transfer precision. Other implementations of CCIIs not based on the aforementioned topologies have also been proposed, such as translinear-loop based CCII [13] with large bandwidths (2-3 GHz in 0.35 μm CMOS) and a low R_{X} below 20Ω. This improvement comes at the price of a larger transfer error of 4%. Other recent CCII implementations based on a flipped voltage follower [14] and floating current source [15], [16] have also been proposed. In [14], low-power operation is achieved (less than 100 μW) and low THD (Total Harmonic Distortion) of less than 0.21% with a transfer error of less than 0.01% at the cost of bandwidth reduction (less than 60 MHz in 0.35 μm CMOS). In [15] a large bandwidth of ˜600 MHz (1 μm CMOS) with R_{X}<15Ω is presented.

An analysis of the state-of-the-art in published literature therefore indicates that open-loop designs achieve higher bandwidths than designs with closed-loop feedback, but at the expense of poorer transfer precision and higher RX values. On the other hand, closed-loop designs boast excellent precision and low RX values but at the expense of lower bandwidths.

Besides having narrower operating bands, closed-loop CCIIs are also susceptible to instability, especially at higher frequencies. Despite this risk, stability analysis in CCIIs has received minimal attention in the literature. Even though a general approach [17] to the feedback analysis of low output impedance circuits (such as CCIIs), often an analytical approach at high frequencies is too complex to attempt. Furthermore, analytical methods typically fail to account for multiple loops which, if not explicitly created in the CCII circuit design, may exist through parasitic elements. Besides possible instability, feedback loops often also cause gain peaking at the upper frequency band-edge, with the only work [9] in addressing this problem through peaking reduction. The stability problem is often compounded by changing load impedance and environmental conditions during operation, as well as process variation. The Applicant believes that this problem requires post-production tunable phase margin and peaking control, which has never been addressed in literature.

Another shortcoming in the body of literature on CMOS CCIIs is a lack of published measurement data. In many publications [5], [9]-[16], all results are based on simulations. Furthermore, few papers consider practicalities of device manufacturing such as non-ideal effects, process corners and random variation, device parasitics, and stability considerations. To the Applicant's knowledge, no disclosure describing a physical implementation (with measurement results) of a high bandwidth, high precision CMOS CCII has ever been published. This may have contributed to manufacturers' aversion to commercial adoption of CCIIs [4].

Accordingly, the Applicant desires, and it may be an object of the invention to provide, one or more of the following:
A post-production tunable RC (Resistor-Capacitor) compensation network to reduce gain peaking, tune the phase margin to ensure stability despite process variation and introduce a trade-off mechanism between bandwidth, precision and R_{X}.
A practical CCII design methodology incorporating explicit stability analysis with accurate device models, process variation, and layout parasitics.
Optimisation based synthesis technique is presented and implemented in 0.35 μm CMOS, improving on the state-of-the-art CCII+ in with an operating bandwidth exceeding 500 MHz, R_{X} lower than 5Ω and a transfer error lower than 1%.

### SUMMARY OF INVENTION

Accordingly, the invention provides a Second Generation Current Conveyor (CCII) having a three-port network with ports designated as X, Y, and Z, wherein the CCII includes:
a tunable feedback network.

The tunable feedback network may be provided between at least two of the ports. The tunable feedback network may be provided between ports Z and Y.

The tunable feedback network may be post-production tunable. The tunable feedback network may be used to compensate for process tolerances.

The tunable feedback network may be implemented to reduce passband ripple.

The tunable feedback network may yield a CCII with both a large bandwidth and high precision.

The tunable feedback network may comprise a tunable RC network. The tunable RC network may be in the form of a tunable RC Miller network. The RC Miller network may comprise a capacitive element and a resistive element. The resistive element may include at least one solid-state element. The resistive element may be a MOS (Metal-Oxide Semiconductor) device or a MOS resistor. A resistance offered by the resistive element may be voltage-controlled or voltage-variable. The capacitive element may include at least one solid-state element. The capacitive element may be a varactor. A capacitance offered by the capacitive element may be voltage-controlled or voltage-variable. Accordingly, feedback characteristics, or other characteristics, of the tunable feedback network may be adjusted by adjusting a voltage applied to the resistive element and/or the capacitive element.

The tunable feedback network may be tunable to adjust one or more of the following characteristics:
gain peaking, e.g., to reduce gain peaking;
tune the phase margin, e.g., to ensure stability despite process variation; and
introduce a trade-off mechanism between bandwidth, precision and R_{X}.

The tunable feedback network may include a plurality of transistors. One or more of the transistors in the tunable feedback network may form part of one or more of the following:
a differential voltage stage a differential voltage follower stage which mirrors the voltage from port Y to X;
saturated stages to reduce any voltage differential across a current mirror between ports X and Z;
an AC feedback path; and/or
current mirroring sources.

The CCII may be implemented in CMOS (Complementary Metal-Oxide Semiconductor). The CCII may be implemented in 0.35 μm CMOS. The CCII may have an operating bandwidth exceeding 500 MHz. The CCII may have R_{X} lower than 5Ω. The CCII may have a transfer error lower than 1%.

The CCII may be analysed using a multi-loop feedback analysis methodology based on the true return ratio approach [18], as well as multi-loop feedback theory [19], to design the tunable feedback network. Stability analysis proposed in [10] may be applied to the CCII to verify the efficacy of the approach, using two feedback loops.

### BRIEF DESCRIPTION OF DRAWINGS

The invention will now be further described, by way of example, with reference to the accompanying diagrammatic drawings.

In the drawings:

FIG. 1 shows a PRIOR ART schematic circuit diagram for single-loop feedback analysis using the double-injection technique;

FIG. 2 shows a possible schematic signal flow graph representation of FIG. 1;

FIG. 3 shows a schematic circuit diagram of a CCII circuit, in accordance with the invention;

FIG. 4a shows a graph of simulated voltage transfer curves between ports Y and X for various process corners for a fixed R_{L} of 50Ω for the CCII of FIG. 3;

FIG. 4b shows a graph of simulated current transfer curves between ports X and Z for various process corners for a fixed R_{L} of 50Ω for the CCII of FIG. 3;

FIG. 4c shows a simulated voltage transfer curves for various R_{L} values for the CCII of FIG. 3;

FIG. 4d shows a graph of simulated voltage transfer curves for various R_{L} values for the CCII of FIG. 3;

FIG. 5 shows a graph of port impedance magnitudes of the CCII of FIG. 3 as a function of frequency;

FIG. 6a shows a Nyquist plot of the feedback loop of the CCII in FIG. 3 for various values of r_{fb};

FIG. 6b shows a root-locus plot of closed loop gain for varying values of the graph in FIG. 6a;

FIG. 6c shows a Nyquist plot of the feedback loop of the CCII of FIG. 3 for various values of R_{L};

FIG. 6d shows a Bode diagram corresponding to FIG. 6c for various values of R_{L};

FIG. 7 shows a probability density function of the phase margin for the CCII of FIG. 3 across process design corners (based on Monte Carlo analysis);

FIG. 8 shows a micrograph of the CCII of FIG. 3;

FIG. 9 shows a test PCB (Printed Circuit Board) for housing and testing the CCII of FIG. 3;

FIG. 10a shows a graph of measured voltage transfer curve of the CCII of FIG. 3;

FIG. 10b shows graph of measured input versus output sinusoid signals for two frequencies across the passband of FIG. 3;

FIG. 11 shows a schematic PRIOR ART circuit of a high-precision CCII presented in [10];

FIG. 12 shows a micrograph of a top view of the CCII of FIG. 11;

FIG. 13a shows a Nyquist plot of the effective open-loop gain of the CCII in FIG. 11 for varying R_{L};

FIG. 13b shows a Bode plot of the open loop gain of FIG. 13a;

FIG. 13c shows a root-locus plot of a closed-loop gain for varying R_{L} in the CCII of FIG. 11;

FIG. 13d shows a Nyquist plot of T₁′ for varying R_{L} in the CCII of FIG. 11;

FIG. 13e shows a measured output response of in the CCII of FIG. 11; and

FIG. 13f shows an FFT of measured output response of FIG. 13e.

### DETAILED DESCRIPTION OF EXAMPLE EMBODIMENT

The following description of the invention is provided as an enabling teaching of the invention. Those skilled in the relevant art will recognise that many changes can be made to the embodiment described, while still attaining the beneficial results of the present invention. It will also be apparent that some of the desired benefits of the present invention can be attained by selecting some of the features of the present invention without utilising other features. Accordingly, those skilled in the art will recognise that modifications and adaptations to the present invention are possible and can even be desirable in certain circumstances, and are a part of the present invention. Thus, the following description is provided as illustrative of the principles of the present invention and not a limitation thereof.

First, the Applicant provides an explanation of techniques used to design and analyse a CCII in accordance with the invention.

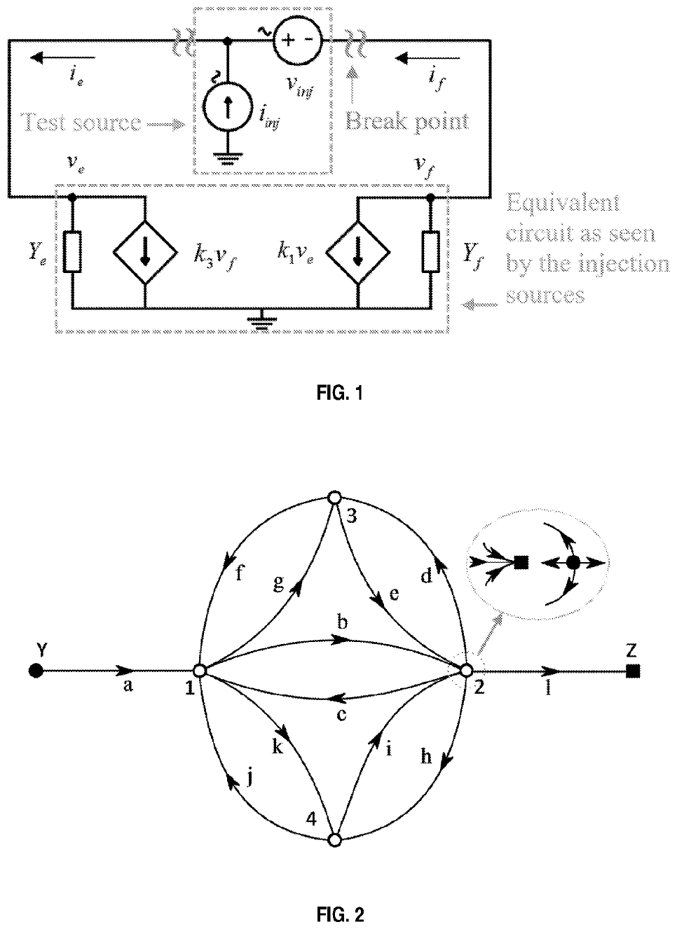

Single-loop feedback theory is based on Bode's definition of the return ratio

$$T = - \frac{{v}_{f}}{{v}_{e}} = - \frac{{i}_{f}}{{i}_{e}} , \qquad ( 2 )$$

where vₑ and iₑ represent the injected and v_{f} and i_{f} the returned signals, as shown in FIG. 1 [18].

Bode's original theory requires replacing an existing dependent source (that models the active device—typically current or voltage gain) with an independent test source, which is not always possible, especially if black-box models are used. This limitation is overcome by Middlebrook's and Tian's subsequent extensions to single-loop feedback theory [18]. Using Middlebrook's approach, the feedback loop can be “cut” at any point that breaks all possible feedback loops, and a test source is inserted in the loop at the break, as shown in FIG. 1. The test source consists of both a current and voltage source to maintain the original DC impedances at both break point terminals. Tian's approach further accounts for reverse and forward loop transmission effects as modeled by the two dependent sources, k₁ and k₃ [18].

The return ratio, can be derived from (2) and FIG. 1 using Kirchhoff's laws, resulting in the equations [18]:

$$\begin{matrix} T = \frac{2 ( AD - BC ) - A + D}{2 ( BC - AD ) + A - D + 1} , \\ where & ( 3 ) \\ A = \frac{- {k}_{1} - {Y}_{f}}{{k}_{1} + {k}_{3} + {Y}_{e} + {Y}_{f}} , B = \frac{{Y}_{e} {Y}_{f} - {k}_{1} {k}_{3}}{{k}_{1} + {k}_{3} + {Y}_{e} + {Y}_{f}} , C = \frac{1}{{k}_{1} + {k}_{3} + {Y}_{e} + {Y}_{f}} , D = \frac{{k}_{3} + {Y}_{f}}{{k}_{1} + {k}_{3} + {Y}_{e} + {Y}_{f}} . & ( 4 )\end{matrix}$$

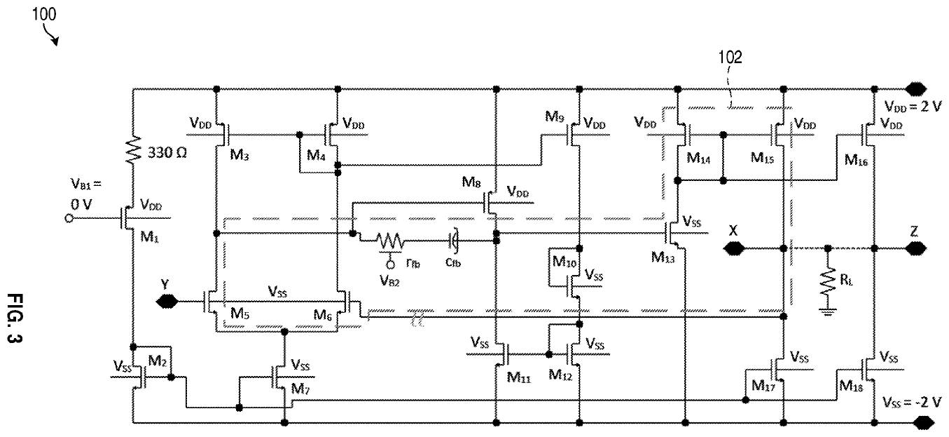

Next, using Mason's multi-loop feedback theory [19], the single-loop cut approach is extended to multi-loop systems. As an example, the CCII+ in [10] can be represented by the signal flow graph in FIG. 2.

All feedback loops, as well as the source and sink, are indicated. Mason has shown that the denominator of the transfer gain (denoted by Δ) is given by [19]

Δ=1−ΣₘPₘ₁+ΣₘPₘ₂−ΣₘPₘ₃+ . . . , (5)

where Pₘᵣ is the gain product of the m^{th} possible combination of r non-touching loops where r>0. For example, in FIG. 2, 10 feedback loops can be identified as:

T₁=ed, T₂=fg, T₃=jk, T₄=hi, T₅=gec, T₆=kic, T₇=dfb, T₈=hjb, T₉=fkid, T₁₀=jgeh. (6)

From (5),

Δ=1−Σᵢ₌₁¹⁰Tᵢ+(T₁T₂+T₃T₄), (7)

which can be re-written in the factorised form [19]

Δ=Πₙ1−Tₙ′, (8)

where Tₙ′ is the loop gain of the n^{th} loop with all lower-numbered loops split.

To illustrate the practical implication of (8), node 2 in FIG. 2 is chosen as the starting node in the analysis. The node is split (or cut) by subdividing it into source and sink nodes and the loop gain computed. Next, leaving the previous loop split, the next loop is found and its gain computed. In this analysis, only node 1 is not affected (has a non-zero gain) after the previous split of node 2. Therefore, for this example:

Δ=(1−T₁′)(1−T₂′)=1−T₁′−T₂′+T₁′T₂′, (9)

which has the same form as (7), as expected. In general, Tₙ′≠Tₙ.

Equation (8) is therefore compatible with the aforementioned double-injection cut technique and Δ can be obtained with relative ease, even for complicated cases (in the above example only two cuts were sufficient to isolate 10 loops). It is also compatible with existing numerical approaches, where parts of the signal flow graph might be black box models where the feedback structure is unknown (such as device parasitics of transistor models). Moreover, if a loop or part of a loop is considered twice (which is particularly likely in the black-box scenario) then the computed gain is simply 0 and from (8) results in multiplication of Δ by 1.

Finally, the stability of the network can be determined by solving for the poles of Δ. Alternatively, the effective open-loop gain can be found and a Nyquist plot constructed by:

Δ=1+A(s)F(s), A(s)F(s)=Δ−1, (10)

where A and F are the effective forward and feedback loop gains.

The approach for analysing multi-loop feedback stability therefore consists of the following steps:
1. Identify any potential feedback loop and introduce a break-point anywhere in the loop. Choosing loops which touch other loops is desirable as this reduces the analysis time.
2. Apply the single loop feedback double injection analysis technique to calculate the return ratio Tₙ′.
3. Identify any remaining feedback loop that still exists with the previously identified loop(s) cut.
4. Repeat steps 2 and 3 until no more feedback loops can be found.
5. Calculate Δ using (8) and the effective open-loop gain using (10) if desired.

Having formulated a multi-loop feedback analysis technique compatible with the envisaged numerical circuit design practices, the design and analysis of CCII in accordance with the invention may be disclosed and discussed.

FIG. 3 illustrates a circuit 100 of an example CCII in accordance with the invention. In the circuit 100, the indicia Mₓ refer to transistors and Vₓₓ refer to reference voltages. A tunable feedback network 102 is demarcated by broken lines. Three ports of the CCII 100 are indicated by X, Y, and Z.

An input of the circuit 100 is a differential voltage follower stage (M₃-M₇) which mirrors the voltage from port Y to X. A simple current mirror then conveys the current from port X to Z. Transistor M₈ ensures that M₅ operates in saturation and together with M₉ ensures the same DC V_{DS} across M₅ and M₆ (thereby reducing the voltage following error). M₁₃ ensures that V_{DS} across M₈ is similar to that of M₉, further reducing any voltage difference between the two legs of the differential voltage mirror. A high gain (and, subsequently, narrow band) AC feedback path is formed by the common source pair M₈ and M₁₃.

The remaining transistors act as biasing current sources. As a novel extension on [12], the tunable feedback network 102 is rendered tunable by adding a post-production tunable RC Miller network, with r_{fb} and c_{fb} selected to reduce this feedback gain and increase the bandwidth, at the expense of degrading precision and R_{X}. Finally, a load impedance R_{L} of 50Ω terminates both ports X and Z, to represent either external test equipment or a subsequent SoC (Silicon on-Chip) stage. The present design is, however, compatible with an arbitrary value of load impedance. A driving source is assumed to have negligible output impedance, as is common in CCII design.

To increase the bandwidth further and control the resulting tradeoffs, a numerical optimization-based design methodology is implemented. Design equations (11)-(15) are derived to serve as a basis for finding initial design values as well as to guide the numerical optimizations. These equations do not consider parasitic effects, which will only be accounted for in later simulation (using accurate device models supplied by the foundry) during the optimization stage. In the circuit 100, the following are chosen: R_{L}=50Ω, g_{m,vm}=g_{m,5}=g_{m,6}, g_{m,m}=g_{m,14}=g_{m,15}=g_{m,16}, g_{m,fb}=g_{m,13}, g_{m,b2}=g_{m,17}=g_{m,18}, g_{o,b2}=g_{o,17}=g_{o,18}, g_{o,b1}=g_{o,7}, g_{o,vm}=g_{o,5}=g_{o,6}, g_{o,m}=g_{o,14}=g_{o,15}=g_{o,16}, g_{o,fb}=g_{o,13}. gₘ and gₒ represent the transconductances and output conductances of the transistors, respectively. It then follows that:

$$\begin{matrix}β {\vert}_{f = 0} \approx \frac{{R}_{L} {g}_{m , 8} {g}_{m , fb} {g}_{m , m} {g}_{m , vm}}{\begin{matrix}[ {g}_{0 , 8} {g}_{0 , vm} ( {g}_{m , m} + {g}_{0 , fb} ) ( \frac{1}{2} + ( {g}_{o , b 2} + {g}_{o , m} ) {R}_{L} ) + \\ {R}_{L} {g}_{m , 8} {g}_{m , fb} {g}_{m , vm} ]\end{matrix}} , & ( 11 ) \\ α {\vert}_{f = 0} \approx \frac{{R}_{L} {g}_{m , 8} {g}_{m , fb} {g}_{m , m} {g}_{m , vm}}{\begin{matrix}( {R}_{L} {g}_{0 , b 2} + {R}_{L} {g}_{0 , m} + 1 ) ( {g}_{o , 8} {g}_{0 , vm} ( {g}_{0 , b 2} + {g}_{0 , m} ) \\ ( {g}_{m , m} + {g}_{0 , fb} ) {g}_{m , 8} {g}_{m , m} {g}_{m , fb} {g}_{m , vm} )\end{matrix}} , & ( 12 ) \\ {Z}_{X} \approx \frac{s \cdot {c}_{fb} ( {g}_{m , 8} + {g}_{o , vm} ) ( {g}_{m , vm} + {g}_{o , vm} )}{\begin{matrix}{g}_{m , fb} {g}_{m , vm} ( s \cdot ( {r}_{fb} {c}_{fb} {g}_{m , 8} - {C}_{fb} ) + \\ {g}_{m , 8} ) ( {g}_{m , vm} + {g}_{o , vm} )\end{matrix}} , & ( 13 ) \\ {Z}_{Y} \approx \frac{s \cdot 4 {c}_{gs , vm} + 2 ( 2 {g}_{m , vm} + ( 2 {g}_{m , vm} + {g}_{o , b 1} ) )}{s \cdot {c}_{gs , vm} ( 2 {g}_{b , vm} + {g}_{o , b 1} )} , & ( 14 ) \\ {R}_{Z} \approx \frac{1}{{g}_{o , b 2} + {g}_{o , m}} . & ( 15 )\end{matrix}$$

Based on these design equations, the following parametric choices may be important:
To reduce the transfer error, R_{X} and increase R_{Z}, the parameters g_{o,vm}, g_{o,8}, g_{o,m}, g_{o,b2}, g_{o,fb} should be minimised.
To increase Z_{Y} at higher frequencies, g_{b,vm} and g_{o,b1} should be minimised.
To reduce R_{X} and also minimise the transfer error (both in α and β), g_{m,fb}, g_{m,m}, g_{m,vm} should be maximised.

Initial design values are chosen with these considerations in mind, as shown in Table 1.

TABLE 1

| Device | W/L (μm/μm) |
|---|---|
| M1 | 5/0.5 |
| M2 | 5/0.35 |
| M3 | 5/0.35 |
| M4 | 5/0.35 |
| M5 | 20/0.35 |
| M6 | 20/0.35 |
| M7 | 5/0.35 |
| M8 | 5/0.35 |
| M9 | 5/0.35 |
| M10 | 5/0.35 |
| M11 | 5/0.35 |
| M12 | 5/0.35 |
| M13 | 30/0.35 |
| M14 | 20/0.35 |
| M15 | 20/0.35 |
| M16 | 20/0.35 |
| M17 | 10/0.35 |
| M18 | 10/0.35 |

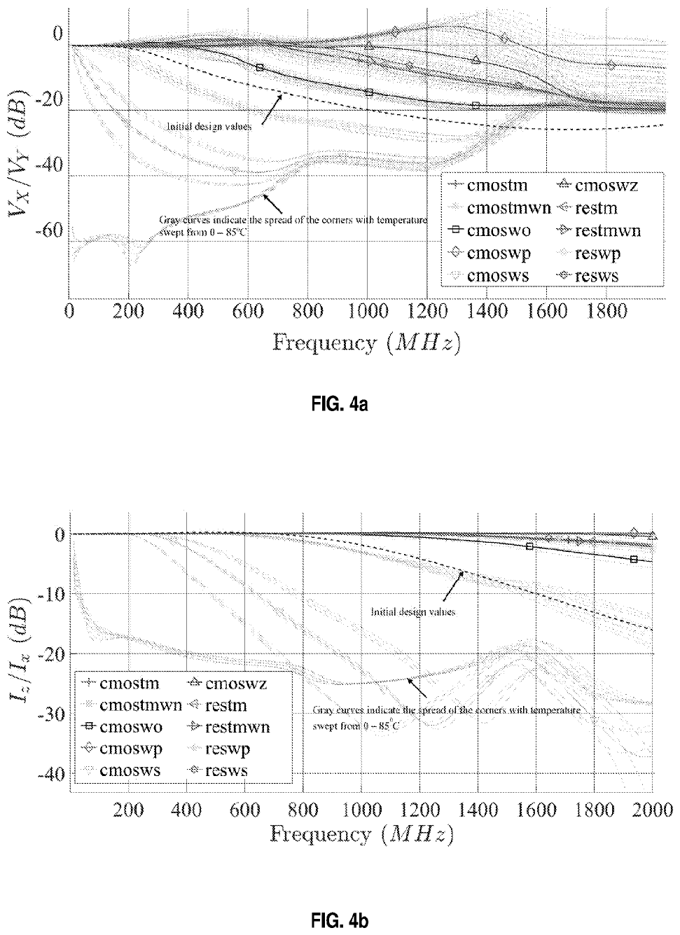

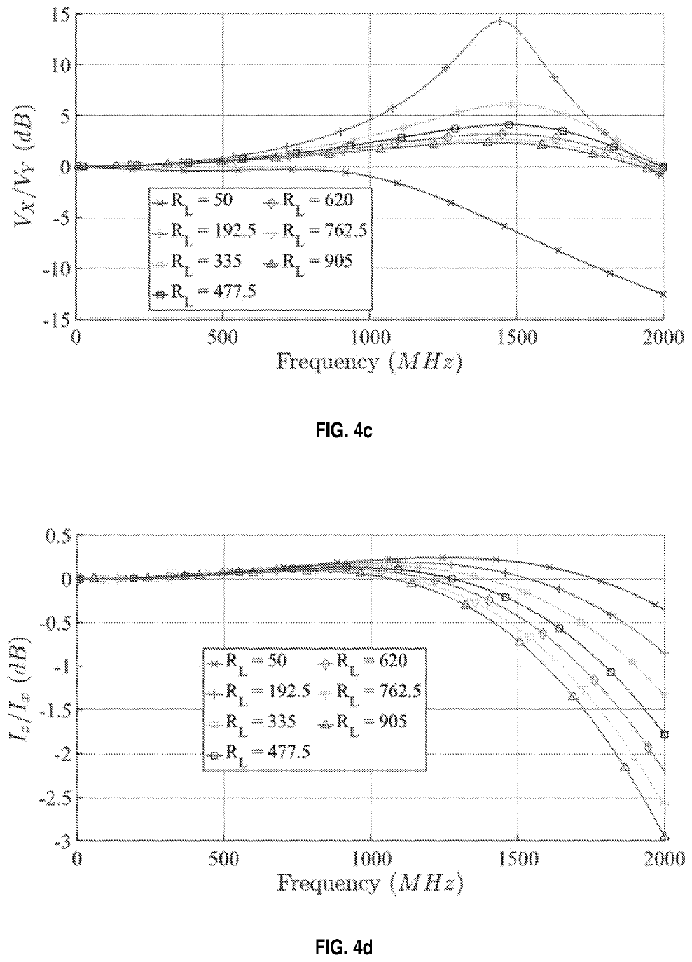

Initial values for r_{fb} and c_{fb} are set to 1 kΩ and 100 fF, respectively. The resulting transfer curves for R_{L}=50Ω and initial design values are shown in FIGS. 4a-4b.

Next, a robust global optimization is run until the design goals as shown in Table 2 are met.

TABLE 2

| Goal | Quantity | Requirement | | Weight |
|---|---|---|---|---|
| 1 | V_{0 V(i)} = \|V_{DS}(Mᵢ)\| − V_{DSAT}(Mᵢ)∀i | >300m | | 5 |
| 2 | I_{fT(i)} = \|I_{DS}(Mᵢ) − W_{Mi} · 100μ\|, i ∈ | <10% | | 2 |
| | {5, 6, 13, 14, 15, 16} | | | |
| 3 | β\|_{f=0 Hz} = V̅_̅{̅X̅}̅/̅V̅_̅{̅Y̅}̅_{_{f=0 Hz}} | <0.05% | | 1 |
| 4 | B_{BW} = BW_{-3bB}(V_{X}/V_{Y}) | >700 | MHz | 2 |
| 5 | Bᵣᵢₚₚ = Δₘₐₓ(\|V_{X}/V_{Y}\|) | <3 | dB | 1 |
| 6 | α\|_{f=0 Hz} = (̅I̅_̅{̅Z̅}̅/̅I̅_̅{̅X̅}̅)̅_{f=0 Hz} | <0.1% | | 1 |
| 7 | α_{BW} = BW_{-3bB}(I_{Z}/I_{X}) | >1 | GHz | 2 |
| 8 | αᵣᵢₚₚ = Δₘₐₓ(\|I_{Z}/I_{X}\|) | <3 | dB | 1 |

Goal 1 sets an overvoltage requirement of at least 300 mV for each transistor to enforce linear transfer, which is the highest priority. Goal 2 requires transistors that form part of the RF path to be biased for optimal f_{T}, which corresponds to approximately 100 μA per μm gate width. Goals 3-5 and 6-8 aim to reduce transfer errors and increase bandwidth. The −3 dB bandwidth is determined relative to the values of α and β at f=0 Hz.

After running the optimization, the resulting transfer curves are shown in FIGS. 4a-4b for various process corners (R_{L}=50Ω), where the cmostm, restm pair refer to the nominal corner. FIGS. 4c-4d illustrate the behaviour of the CCII 100 for other R_{L} loads. Including the load impedance in the optimization is critical for wideband applications, with high load impedance leading to wider voltage transfer bandwidth at the expense of slightly reduced current transfer bandwidth. In this example, a load impedance is restricted to 50Ω, as required by the external test equipment interface.

Optimized design values are shown in Table 3, with optimal values for r_{fb} and c_{fb} found as 1.2 kΩ and 360 fF, respectively.

TABLE 3

| Device | W/L (μm/μm) |
|---|---|
| M1 | 12.8/0.5 |
| M2 | 5/0.35 |
| M3 | 10/0.35 |
| M4 | 10/0.35 |
| M5 | 45/0.35 |
| M6 | 45/0.35 |
| M7 | 35/1.25 |
| M8 | 15/0.35 |
| M9 | 10/0.35 |
| M10 | 15/0.35 |
| M11 | 15/0.35 |
| M12 | 15/0.35 |
| M13 | 50/0.5 |
| M14 | 60/0.35 |
| M15 | 60/0.35 |
| M16 | 60/0.35 |
| M17 | 5/0.35 |
| M18 | 5/0.35 |

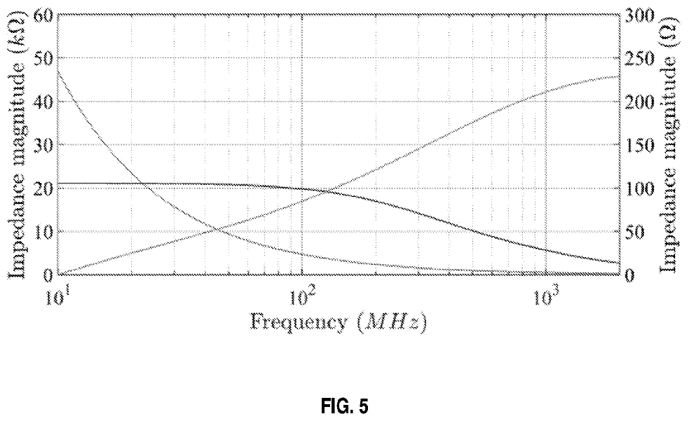

Resulting impedance magnitudes at the various ports are further shown in FIG. 5 at DC R_{X}<5Ω.

Next, the stability of the optimised CCII 100 is investigated and suitable values for r_{fb}, c_{fb}, which may be used by the post-production tuning mechanism, are determined.

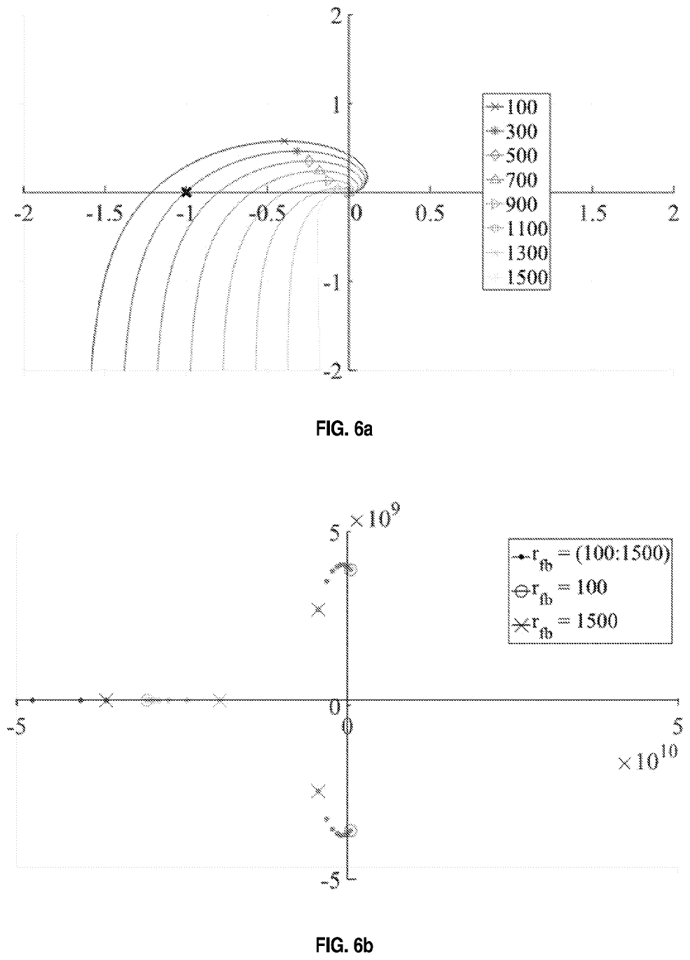

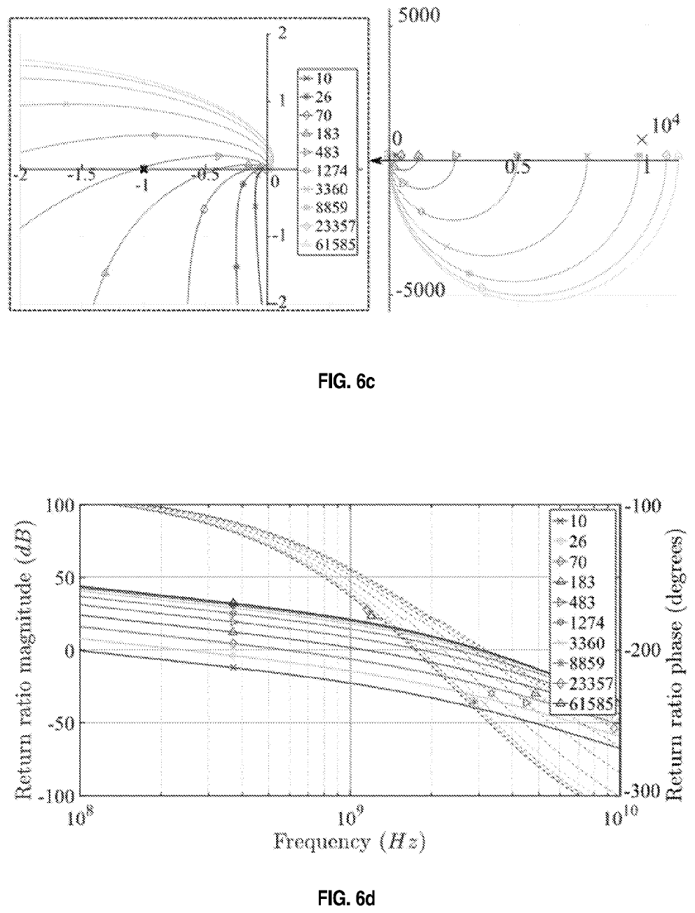

Applying the stability analysis procedure presented above, a single feedback path can be found that breaks all loops, as indicated by the dotted line in FIG. 3. The loop is cut at the gate of M6 (as indicated in FIG. 3) and the return ratio is calculated for r_{fb}∈(100:1.5 k) Ω and c_{fb}=360 fF, resulting in the Nyquist plot in FIG. 6a and matching root-locus plot of the closed-loop gain in FIG. 6b, obtained independently by calculating the roots of the transfer function (not using Δ). The indicated poles move into the RHP for r_{fb}<300Ω. Therefore, for c_{fb}=360 fF, r_{fb}>300Ω ensures a stable design, confirming that the present optimised design is indeed stable. It is easy to incorporate this step into the numerical optimisation procedure above as an additional high-priority goal (as opposed to running the check after the optimisation), but is presented here separately for the sake of clarity. The effects of varying the load resistance are further investigated for r_{fb}=1.2 kΩ in FIGS. 6c-6d which show that the design is unstable for load impedances larger than 480Ω. This again shows that high-precision CCIIs should be designed and optimised with the expected load in place to achieve stability.

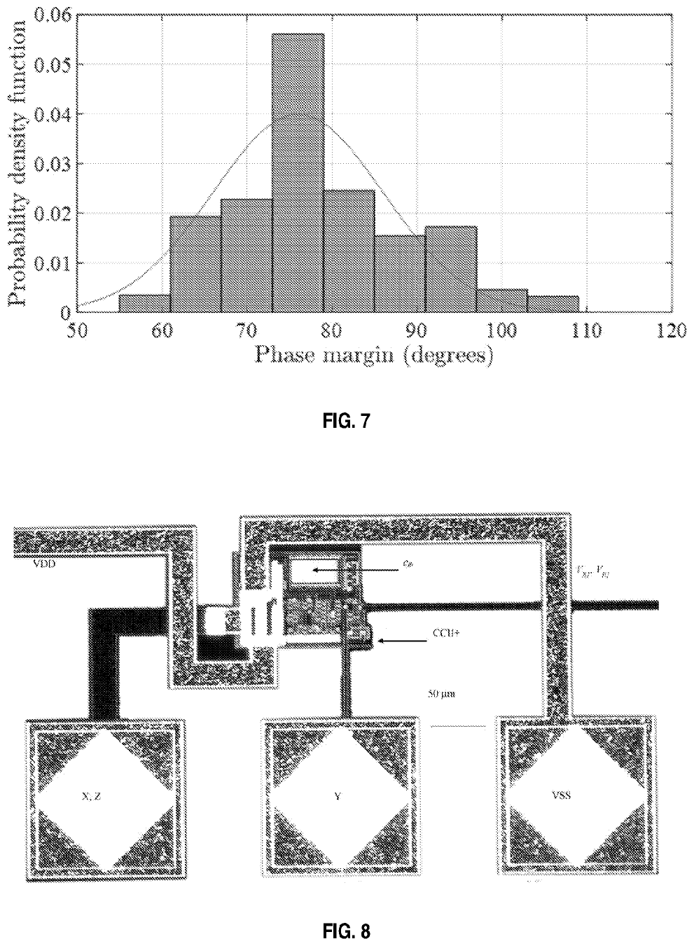

Finally, it is also important to consider the effects of process tolerances on stability, as shown in FIG. 7. Even though post-production tunability of the feedback gain is evidently not necessary in this case to ensure a stable design, it will be used to control peaking, therefore reducing passband ripple, as shown later. To this end, r_{fb} is implemented as an NMOS (Negative Metal Oxide Semiconductor) operating in the triode region with V_{B2} used to tune the effective channel resistance. The transistor aspect ratio is chosen such that, for V_{B2}=V_{SS}, the channel resistance is 300Ω. By reducing V_{B2} the effective resistance can be tuned up to 2 kΩ.

The CCII 100 may be manufactured using the AMS AG 0.35 μm CMOS process. A micrograph of the top-view is shown in FIG. 8 (with the background removed for clarity). The feedback capacitor (c_{fb}) occupies a significant portion of the IC real estate. This illustrates an advantage of using the Miller-effect in the proposed design, as the capacitor would be even larger without it. Power supply lines as well as bondpads are clearly visible.

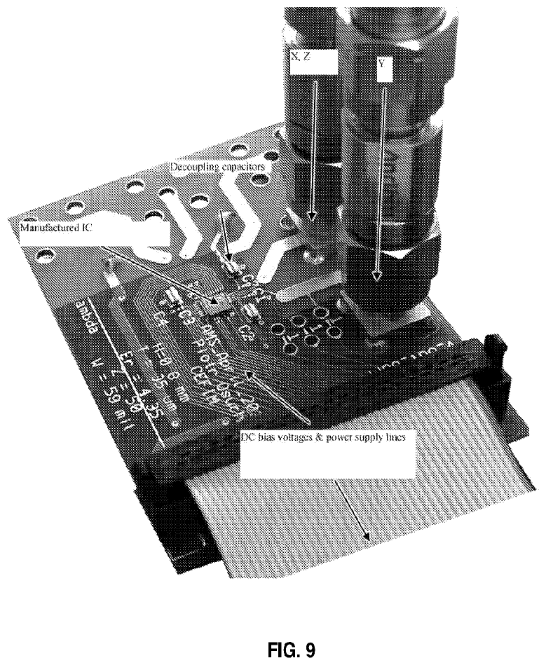

A PCB is designed to house the IC and supply the necessary bias voltages and RF test signals, as shown in FIG. 9. Bondwires are used to connect the IC to the PCB pads.

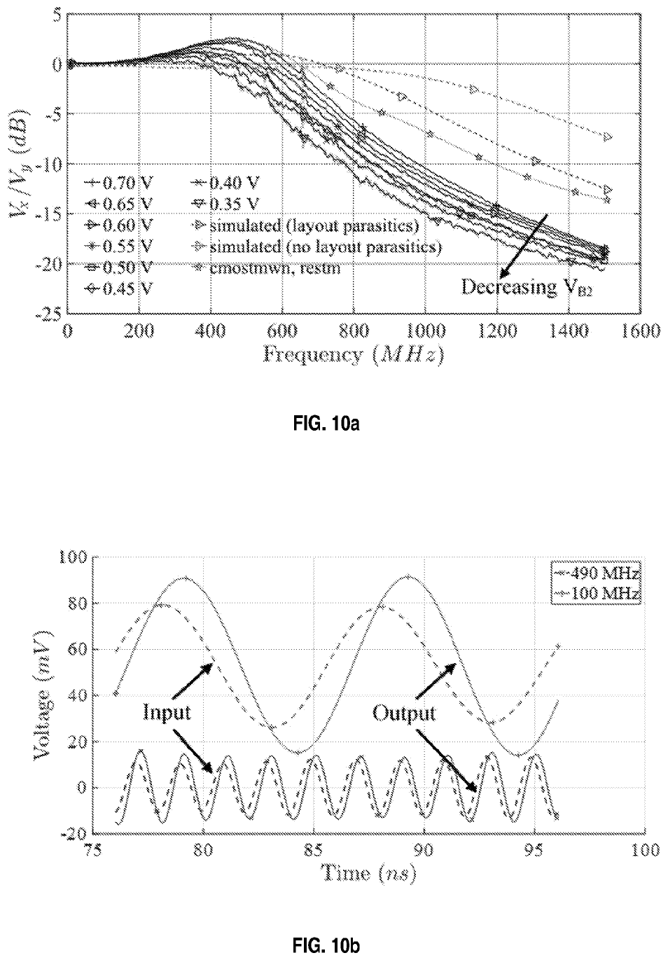

Measured results are shown in FIG. 10. Including layout parasitics in the simulation (using an RC layout extraction) reduces the bandwidth from 1 GHz (in the nominal corner) to 850 MHz. Measured data indicates a further reduction of bandwidth to 500 MHz, which would indicate operation in the (cmostmwn, restm) process corner, as shown. As illustrated, including layout parasitics and considering various design corners in the circuit simulations is paramount to obtain accurate results. Moreover, since process tolerances alone lead to a bandwidth variation of more than 100%, worst-case corners should be considered for the intended application. The post-production tunability of r_{fb} (through variation of V_{B2}) is used to fine-tune the resulting voltage following curve as seen in FIG. 10a. A flat passband with 0.1 dB ripple (1.15% transfer error, though this is exacerbated by measurement noise) and a bandwidth of 500 MHz is obtained for VB2=0.35 V. Input versus output sinusoid responses are measured with a digital oscilloscope and further shown in FIG. 10b for two different frequencies, with the calculated THD shown in Table 4.

TABLE 4

| Frequency (MHz) | THD measured (dBc) | THD simulated (dBc) |
|---|---|---|
| 100 | −20 | −19 |
| 500 | −11 | −6 |

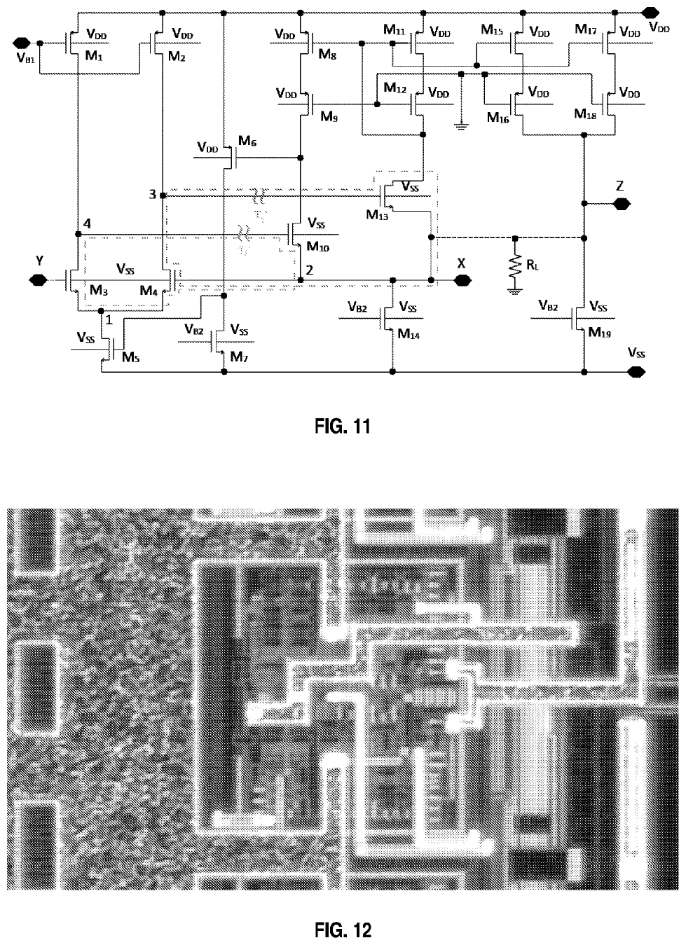

To illustrate further the importance of performing a stability analysis when designing high-precision CCIIs, the simulated CCII proposed in [10] is implemented in 0.35 μm CMOS and manufactured without stability analysis, as shown in FIG. 11. A circuit schematic of the resulting CCII is shown in FIG. 12. Transistor aspect ratios are chosen as indicated in Table 5. Once again, for measurement purposes, terminals X and Z are terminated in R_{L}=50Ω.

TABLE 5

| Device | W/L (μm/μm) |
|---|---|
| M1 | 100/0.35 |
| M2 | 100/0.35 |
| M3 | 100/0.35 |
| M4 | 100/0.35 |
| M5 | 30/0.35 |
| M6 | 8/0.35 |
| M7 | 3.5/0.35 |
| M8 | 60/0.35 |
| M9 | 60/0.35 |
| M10 | 100/0.35 |
| M11 | 60/0.35 |
| M12 | 60/0.35 |
| M13 | 100/0.35 |
| M14 | 35/0.35 |
| M15 | 60/0.35 |
| M16 | 60/0.35 |
| M17 | 60/0.35 |
| M18 | 60/0.35 |
| M19 | 35/0.35 |

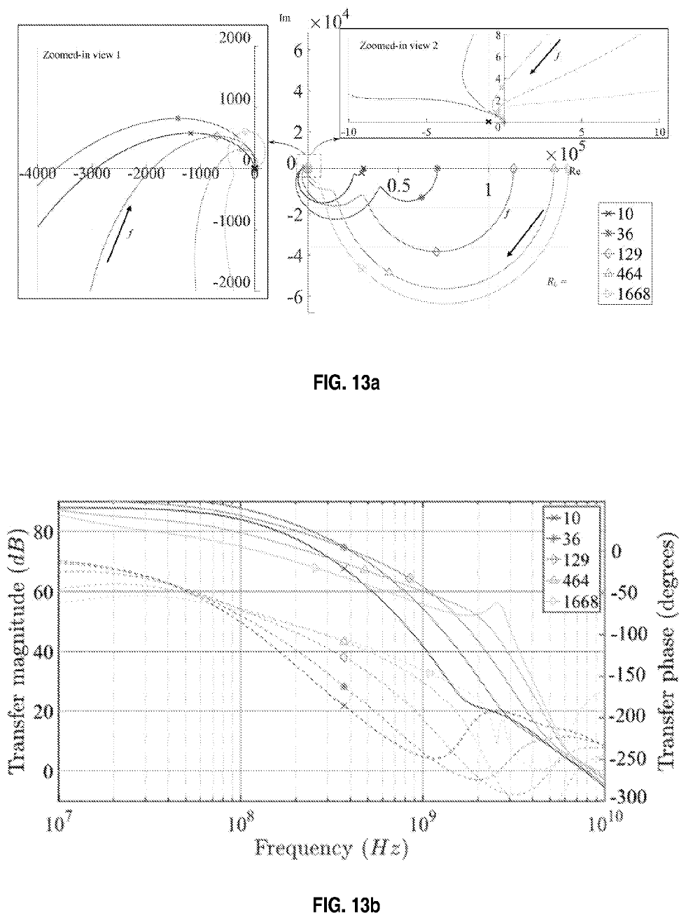

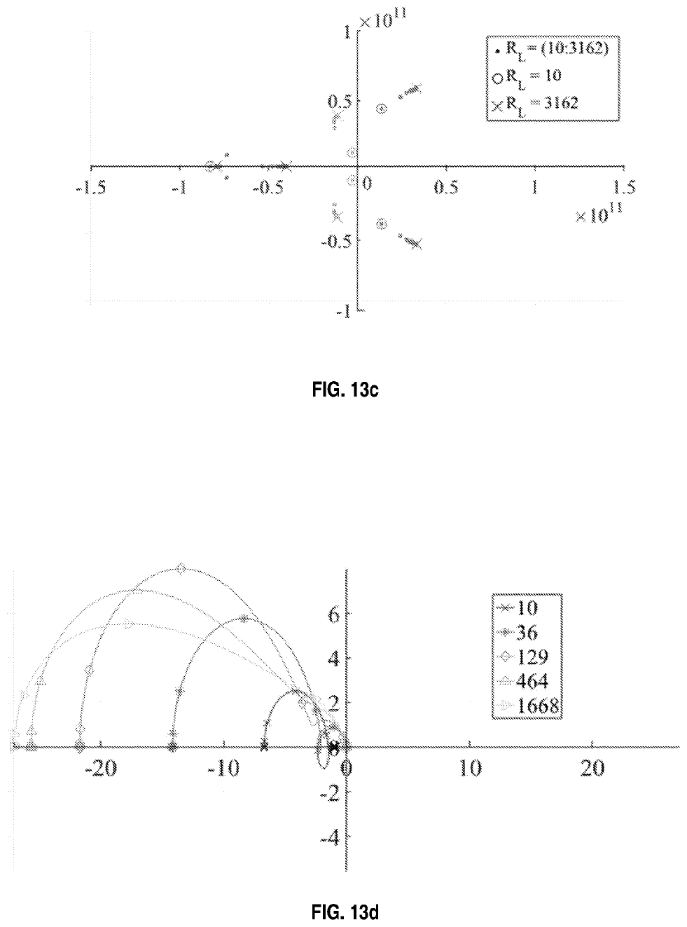

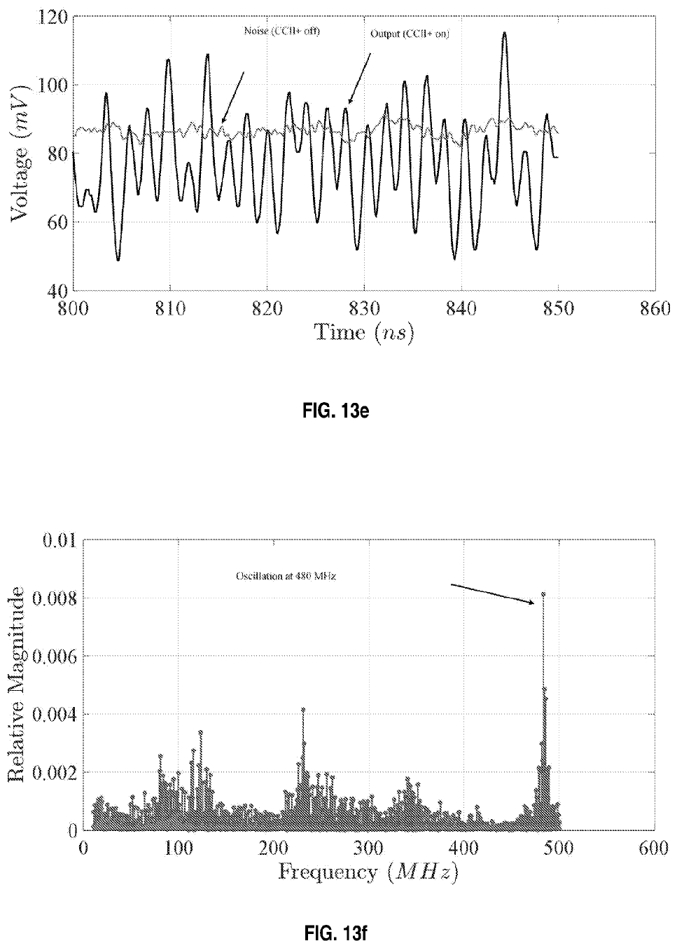

Next, the multi-loop analysis described above is performed on the circuit. Two feedback loops are identified as shown in FIG. 12 (with numbered circuit nodes corresponding to specific graph nodes in FIG. 2). The return ratio of T₁′ is found first (with loop T₂′ left intact) after which T₂′ is found with loop T₁′ open-circuited. Using (8) and (10), the effective open-loop gain is computed as shown in FIGS. 13a-13b for various values of R_{L}. The validity of the proposed multi-loop feedback analysis is confirmed by FIG. 13c where the closed-loop poles are computed independently by calculating the roots of the transfer function (not using Δ from the injection-based cut approach). It is clear that the CCII is unstable for all R_{L}∈(10:1.7 k) Ω. For R_{L}=50Ω, oscillation is expected at ˜500 MHz. In contrast, the analysis considering only the return ratio T₁′ of the first loop is computed as shown in FIG. 13d, and is clearly incomplete when compared to FIG. 13c. Finally, to confirm the theoretical analysis, the manufactured CCIIs output response is measured as shown in FIGS. 13e-13f for R_{L}=50Ω.

The oscillation frequency is measured as 480 MHz, which corresponds well to the theoretical prediction of ˜500 MHz. This result further supports the validity of the presented multi-loop analysis methodology.

The Applicant believes that the invention as described in the example embodiment discloses a high-precision, high bandwidth CMOS CCII with a post-production tunable phase margin and peaking compensation network. A transfer error of roughly 1.15% is achieved with a bandwidth of 500 MHz and R_{X}<5Ω in 0.35 μm CMOS. A practical numerical optimisation based design methodology has been presented using accurate device models as well as layout parasitics, allowing good agreement with measured results to be obtained. It has been shown that process tolerances can result in more than 100% bandwidth variation, with layout parasitics contributing up to 20% in bandwidth reduction. This illustrates the need for detailed corner and layout parasitic simulations during design stages. Additionally, a rigorous multi-loop feedback analysis methodology has been applied to the design and analysis of CCIIs for the first time. It is shown, using an example of a high-precision CCII from literature and measured results, that failure to perform a multi-loop analysis can lead to an unstable design.

The Applicant believes that a field of application of the CCII as described in an example embodiment is in high-speed microelectronic design, particularly used in telecommunications systems and devices. With the continuously increasing speed requirements of modern telecommunication and data processing systems and the bandwidth, power and cost advantages of analogue solutions over their digital counterparts, CCIIs could play an important role in future high-speed microelectronic design.

### REFERENCES

[1] A. O. Network and E. Cherry, “A second-generation current conveyor and its applications,” IEEE Trans. Circuit Theory, vol. 17, no. 1, pp. 132-134, 1970.
[2] P. Eloranta and C. Toumazou, “First, Second and Higher Order Filter Design Using Current Conveyors,” in Current Conveyors: Variants, Applications and Hardware Implementations. New York: Springer, 2014.
[3] F. Seguin, B. Godara, F. Alicalapa, and A. Fabre, “2.2 GHz all-n-p-n second-generation controlled conveyor in pseudoclass AB using 0.8-μm BiCMOS technology,” IEEE Trans. Circuits Syst. II Express Briefs, vol. 51, no. 7, pp. 369-373, July 2004.W.
[4] A. S. Sedra, G. W. Roberts, and F. Gohh, “The current conveyor: history, progress and new results,” Circuits, Devices Syst. IEE Proc., vol. 137, no. 2, pp. 78-87, 1990.
[5] Surakampontorn, V. Riewruja, K. Kumwachara, and K. Dejhan, “Accurate CMOS-based current conveyors,” IEEE Trans. Instrum. Meas., vol. 40, no. 4, pp. 699-702, 1991.
[6] S. Gupta et al., “Group-delay engineered noncommensurate transmission line all-pass network for analog signal processing,” IEEE Trans. Microw. Theory Tech., vol. 58, no. 9, pp. 2392-2407, 2010.
[7] L. Zou, S. Gupta, and C. Caloz, “Loss-gain equalized reconfigurable C-section analog signal processor,” IEEE Trans. Microw. Theory Tech., vol. 65, no. 2, pp. 555-564, 2017.
[8] C. Caloz, S. Gupta, Q. Zhang, and B. Nikfal, “Analog signal processing: a possible alternative or complement to dominantly digital radio schemes,” IEEE Microw. Mag., vol. 14, no. 6, pp. 87-103, 2013.
[9] G. Palmisano and G. Palumbo, “A simple cmos CCII+,” Int. J. Circuit Theory Appl., vol. 23, no. 6, pp. 599-603, 1995.
[10] U. Yodprasit, “High-precision CMOS current conveyor,” Electron. Lett., vol. 36, no. 7, 2000.
[11] K. Watanabe and H.-W. Cha, “Wideband CMOS current conveyor,” Electron. Lett., vol. 32, no. 14, pp. 1245-1246, 1996.
[12] W. S. Hassanein, I. A. Awad, and A. M. Soliman, “New high accuracy CMOS current conveyors,” AEU—Int. J. Electron. Commun., vol. 59, no. 7, pp. 384-391, 2005.
[13] S. Ben Salem, M. Fakhfakh, D. S. Masmoudi, M. Loulou, P. Loumeau, and N. Masmoudi, “A high performances CMOS CCII and high frequency applications,” Analog Integr. Circuits Signal Process, vol. 49, no. 1, pp. 71-78, 2006.
[14] K. Moustakas and S. Siskos, “Improved low-voltage low-power class AB CMOS current conveyors based on the flipped voltage follower,” in Proceedings of the IEEE International Conference on Industrial Technology, 2013, pp. 961-965.
[15] H. Mostafa and A. M. Soliman, “Novel low-power accurate wide-band CMOS negative-second-generation-current-conveyor realizations based on floating-current-source building blocks,” in 2009 IEEE Toronto International Conference Science and Technology for Humanity (TIC-STH), 2009, pp. 720-725.
[16] A. Awad and A. M. Soliman, “New CMOS realization of the CCII-,” IEEE Trans. Circuits Syst. II Analog Digit. Signal Process, vol. 46, no. 4, pp. 460-463, 1999.
[17] E. Ibaragi, A. Hyogo, and K. Sekine, “A phase compensation technique without capacitors for the CMOS circuit with a very low impedance terminal,” IEICE Trans. Fundam. Electron. Commun. Comput. Sci., vol. 83, no. 2, pp. 236-242, 2000.
[18] M. Tian, V. Visvanathan, J. Hantgan, and K. Kundert, “Striving for small-signal stability,” IEEE Circuits Devices Mag., vol. 17, no. 1, pp. 31-41, 2001.
[19] S. J. Mason, “Feedback theory—some properties of signal flow graphs,” Proc. I.R.E, vol. 41, no. 9, pp. 1144-1156, 1953.
[20] S. J. Mason, “Feedback theory: further properties of signal flow graphs,” Proc. I.R.E, vol. 44, no. 7, pp. 920-926, 1955.

1. A Second-Generation Current Conveyor (CCII) having a three-port network with ports designated as X, Y, and Z, wherein the CCII comprises a tunable feedback network.

2-20. (canceled)

21. The CCII as claimed in claim 1, wherein the tunable feedback network is provided between at least two of the ports.

22. The CCII as claimed in claim 1, wherein the tunable feedback network is provided between ports Z and Y.

23. The CCII as claimed in claim 1, wherein the tunable feedback network is post-production tunable and is configured to compensate for process tolerances.

24. The CCII as claimed in claim 1, wherein the tunable feedback network is configured to reduce passband ripple.

25. The CCII as claimed in claim 1, wherein the tunable feedback network comprises a tunable RC (Resister-Capacitor) network.

26. The CCII as claimed in claim 25, wherein the tunable RC network is in the form of a tunable RC Miller network.

27. The CCII as claimed in claim 25, wherein the tunable RC network comprises a resistive element, which comprises at least one solid-state element.

28. The CCII as claimed in claim 27, wherein the resistive element is a MOS (Metal-Oxide Semiconductor) device or a MOS resistor.

29. The CCII as claimed in claim 27, wherein a resistance offered by the resistive element is voltage-controlled or voltage-variable.

30. The CCII as claimed in claim 25, wherein the tunable RC network comprises a capacitive element, which comprises at least one solid-state element.

31. The CCII as claimed in claim 30, wherein the capacitive element is a varactor.

32. The CCII as claimed in claim 31, wherein a capacitance offered by the capacitive element is voltage-controlled or voltage-variable.

33. The CCII as claimed in claim 1, wherein the tunable feedback network is configured to adjust one or more of the following characteristics:
gain peaking;
tune a phase margin; and/or
introduce a trade-off mechanism between bandwidth, precision and RX.

34. The CCII as claimed in claim 1, wherein the tunable feedback network comprises a plurality of transistors.

35. The CCII as claimed in claim 34, wherein one or more of the transistors in the tunable feedback network form part of one or more of the following:
a differential voltage stage or a differential voltage follower stage, which mirrors the voltage from port Y to X;
saturated stages configured to reduce any voltage differential across a current mirror between ports X and Z;
an AC feedback path; and/or
current mirroring sources.

36. The CCII as claimed in claim 1, which is implemented in CMOS (Complementary Metal-Oxide Semiconductor).

37. The CCII as claimed in claim 36, which has one or more of:
an operating bandwidth exceeding 500 MHz;
an RX lower than 5Ω; and/or
a transfer error lower than 1%.

38. The CCII as claimed in claim 1, which is configured to be tuned using a multi-loop feedback analysis methodology based on a true return ratio approach and multi-loop feedback theory.

39. A method of tuning a CCII as claimed in claim 38, the method comprising using a multi-loop feedback analysis methodology based on a true return ratio approach and multi-loop feedback theory, thereby to tune the tunable feedback network of the CCII.
